(19) United States
(12) Patent Application Publication
(10) Pub. No.: US 2024/0047302 A1
(43) Pub. Date: Feb. 8, 2024

(54) POWER CHIP PACKAGE AND POWER MODULE

(71) Applicant: Ganstronic INC., Tainan City (TW)

(72) Inventors: Cheng-Chuan CHEN, Tainan City (TW); Yu-Feng LIN, Tainan City (TW)

(21) Appl. No.: 18/227,929

(22) Filed: Jul. 29, 2023

Related U.S. Application Data
(60) Provisional application No. 63/370,493, filed on Aug. 4, 2022.

(30) Foreign Application Priority Data
Nov. 17, 2022 (TW) 111143861

(51) Int. Cl. H01L 23/433; H01L 23/367; H01L 23/00; H01L 23/31

(52) U.S. Cl. CPC H01L 23/4334; H01L 23/3672; H01L 24/08; H01L 24/32; H01L 23/3128; H01L 2224/08237; H01L 2224/32237; H01L 2924/186; H01L 2924/1306; H01L 2924/01047; H01L 2924/0105

(57) ABSTRACT

A power chip package and a power module are provided. The power chip package includes a metal cover, a power chip, and a thermal conductive material. A recess is formed on a side surface of the metal cover. The power chip is bonded on the metal cover and is located in the recess. The thermal conductive material fills the recess and surrounds the power chip. At least one first electrode of the power chip is exposed out of the thermal conductive material. The power module includes a circuit board, plural power chip packages and a polymeric resin. The power chip packages are disposed on the circuit board. The polymeric resin packages the power chip packages on the circuit board.

### RELATED APPLICATIONS

This application claims priority to Taiwan Application Serial Number 111143861 filed on Nov. 17, 2022, which claims priority to U.S. Application Ser. No. 63/370,493, filed Aug. 4, 2022. The entire contents of each of which are incorporated by reference.

### BACKGROUND

### Field of Invention

The present invention relates to an electronic power chip package and a power module.

### Description of Related Art

In semiconductor materials, an energy gap is one of the important properties. The semiconductor material with larger energy gap can withstand higher voltage and current intensity, so that the energy conversion efficiency is better. Therefore, the industry devotes much effort to develop high power chips which are made of wide band gap (WBG) materials such as gallium nitride (GaN) or silicon carbide (SiC), and apply the high power chips to high-voltage, high-current, and high-wattage products, such as fast charging devices for electric vehicles, vehicle inverters and on board chargers, or high-voltage power systems.

At present, resin materials are used in the industry to package power chips. Since the resin material is used as the main package body in contact with the outside, a heat conduction effect is limited, and heat generated by the high power chip cannot effectively exit. In other words, the packages suitable for traditional silicon power devices and low power devices cannot meet the high-wattage heat dissipation requirements of wide band gap semiconductors such as gallium nitride (GaN), silicon carbide (SiC) or gallium oxide (Ga₂O₃).

In addition, in the multi-chip module design, in tradition, plural power chips are disposed on a substrate, and then packaged in a chip group in a module. It causes that a heat conduction of the power chip is in difficulty. Therefore, it is necessary to provide a substrate-free power device packaging structure for the variation in module design.

### SUMMARY

The invention provides a power chip package and a power module to solve the heat dissipation due to high power.

According to the aforementioned objectives, the present invention provides a power chip package. The power chip package includes a metal cover, a power chip and a thermal conductive material. The metal cover includes a recess. The recess is formed on a side surface of the metal cover. The power chip is bonded on the metal cover and is located in the recess. The thermal conductive material fills the recess and surrounds the power chip. At least one first electrode of the power chip is exposed out of the thermal conductive material.

According to at least one embodiment of the present invention, the power chip includes a substrate and a semiconductor structure layer. The substrate includes a second electrode bonded on the metal cover. The semiconductor structure is disposed on the substrate, and the first electrode is electrically connected to the semiconductor structure layer.

According to at least one embodiment of the present invention, the substrate is made of one of silicon carbide, silicon, gallium oxide and gallium nitride.

According to at least one embodiment of the present invention, the power chip includes a silicon substrate and a semiconductor structure layer. The silicon substrate is bonded on an inner side of the metal cover. An outer side of the metal cover is grounded. The semiconductor structure layer is disposed on the silicon substrate. The first electrode is connected to the semiconductor structure layer, and the semiconductor structure layer is located between the first electrode and the silicon substrate.

According to at least one embodiment of the present invention, the power chip includes a insulation substrate and a semiconductor structure layer. The insulation substrate is bonded on an inner side of the metal cover. The semiconductor structure layer is disposed on the insulation substrate. The first electrode is connected to the semiconductor structure layer, and the semiconductor structure layer is located between the first electrode and the insulation substrate.

According to at least one embodiment of the present invention, the first electrode includes a primary portion and an extension portion. The primary portion is located between the semiconductor structure layer and the extension portion. A material of the extension portion is selected from a group consisting of tin/silver/copper, tin/copper, tin/sliver, tin/bismuth, tin/antimony.

According to at least one embodiment of the present invention, the thermal conductive material extends to the first electrode.

According to at least one embodiment of the present invention, an end surface of the first electrode is coplanar with an end surface of the thermal conductive material.

According to at least one embodiment of the present invention, the first electrode is protruded out of the end surface of the thermal conductive material.

According to at least one embodiment of the present invention, the thermal conductive material is indirectly connected to the end surface of the first electrode.

According to at least one embodiment of the present invention, the metal cover includes a connecting plate portion and a surrounding wall portion. The power chip is bonded on the connecting plate portion. The surrounding wall portion is formed on an outer edge of the connecting plate portion. The recess of the metal cover is enclosed by the surrounding wall portion and the connecting plate portion.

According to at least one embodiment of the present invention, the metal cover further includes a rough portion. The rough portion is disposed on an inner side surface of the surrounding wall portion.

According to at least one embodiment of the present invention, the metal cover further includes at least one stopper. The stopper is protruded out of the inner side surface of the surrounding wall portion.

According to at least one embodiment of the present invention, the stopper extends to an end surface of the surrounding wall portion.

According to at least one embodiment of the present invention, the stopper is indirectly connected to the end surface of the surrounding wall portion.

According to at least one embodiment of the present invention, a quantity of the stoppers is more than two, one of the stoppers is adjacent to and extends to the end surface of the surrounding wall portion, and another of the stoppers is indirectly connected to the end surface of the surrounding wall portion.

According to the aforementioned objectives, the present invention provides a power module. The power module includes a circuit board, plural power chip packages and a polymeric resin. The power chip packages are disposed on the circuit board. The polymeric resin packages the power chip packages on the circuit board.

According to at least one embodiment of the present invention, the power module includes a heat dissipation fin and an insulation thermal conductive material. The heat dissipation fin is disposed on the metal covers of the power chip packages. The insulation thermal conductive material is disposed on the metal covers of the power chip packages and is located between the metal covers and the heat dissipation fin.

Based on the above, the thermal conductive material is located between the metal cover and the power chip, and the heat generated by the power chip is conducted to the metal cover by using the thermal conductive material. The metal cover may provide a multi-faceted heat dissipation type for effectively improving a heat dissipation effect. The power chip is bonded on the metal cover, which can omit a chip carrier, to be helpful for thinning and lightening, reducing cost, and increasing the variation of the power module.

It is to be understood that both the foregoing general description and the following detailed description are by examples, and are intended to provide further explanation of the invention as claimed.

### BRIEF DESCRIPTION OF THE DRAWINGS

In order to make the above and other objectives, features, advantages, and embodiments of the present invention more obvious, the accompanying drawings are described as follows.

FIG. 1A, FIG. 1B, FIG. 1C, and FIG. 1D are respectively schematic cross-sectional views of power chip packages in accordance with a first, second, third, and fourth embodiments of the present invention.

FIG. 2A to FIG. 2E are cross-sectional views to illustrate a method of the power chip package in accordance with the first embodiment of the present invention.

FIG. 3 is a cross-sectional view to illustrate the power chip package in accordance with the third embodiment of the present invention, showing the power chip package is disposed on a circuit board.

FIG. 4A and FIG. 4B are cross-sectional views to illustrate the power chip package in accordance with the fourth embodiment of the present invention, showing the power chip package is packaged on a circuit board.

FIG. 5 is a cross-sectional view to illustrate the power chip package in accordance with the first embodiment of the present invention, showing the power chip package is packaged on the circuit board.

It is noted that, in accordance with the standard practice in the industry, various features are not drawn to scale. The dimensions of the various features may be arbitrarily increased or decreased for clarity of discussion.

### DETAILED DESCRIPTION

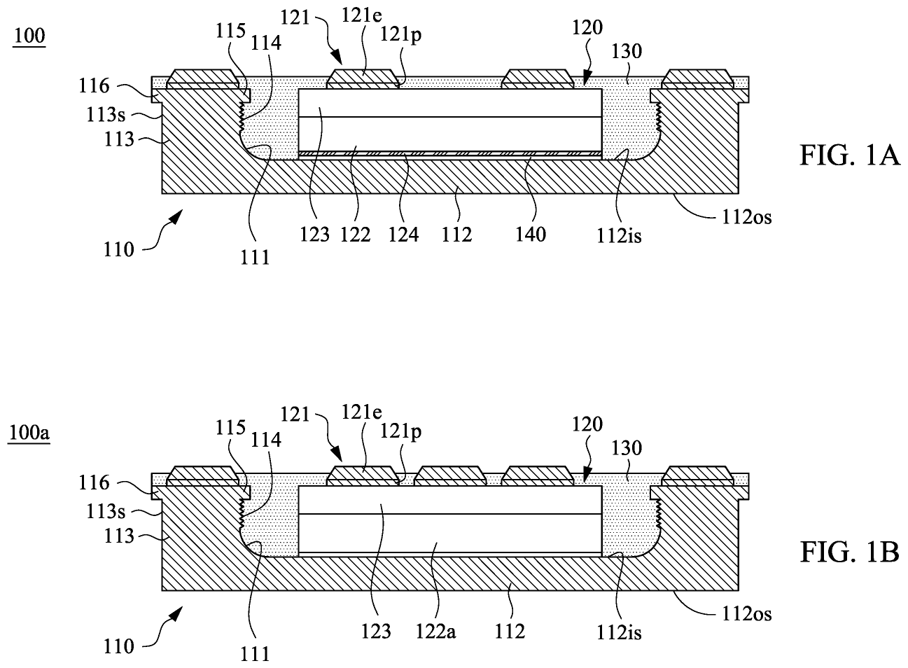

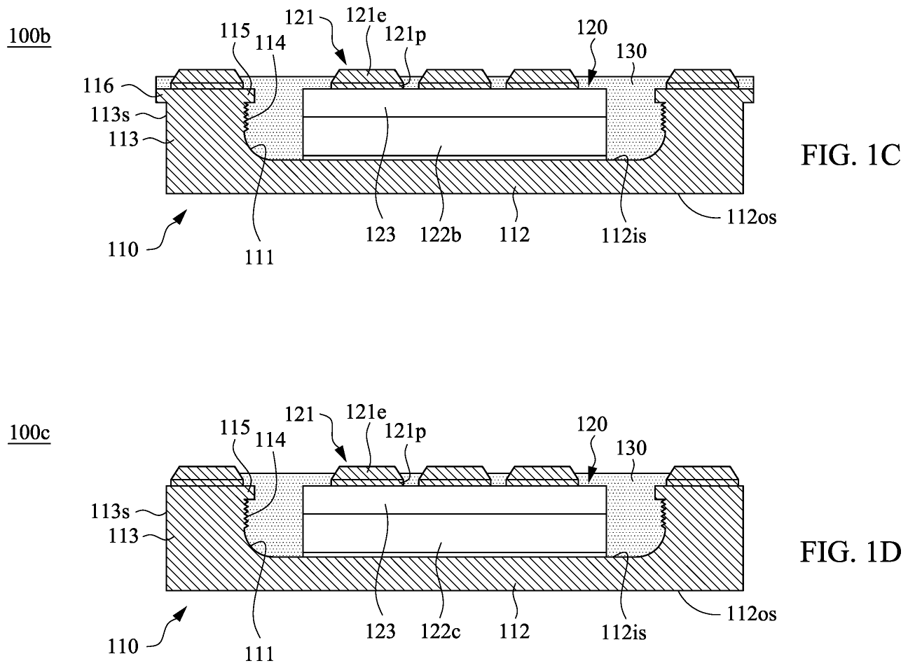

Referring to FIG. 1A, FIG. 1 B, FIG. 1C and FIG. 1D, which are respectively schematic cross-sectional views of power chip packages 100, 100a, 100b and 100c in accordance with plural embodiments of the present invention. The power chip packages 100, 100a, 100b and 100c are high-power power chip packages 100, 100a, 100b and 100c. In each power chip package 100, 100a, 100b and 100c, an area can be 4 mm² to 144 mm², and a power can be greater than or equal to 100 watts, and a preferred power range is between 100 watts and 2000 watts. In some examples, in each power chip package 100, 100a, 100b and 100c, a size may be 6 mm×6 mm, or even 10 mm×10 mm. The power chip package 100, 100a, 100b and 100c includes a metal cover 110, a power chip 120 and a thermal conductive material 130. The metal cover 110 includes a recess 111. The recess 111 is formed on a side surface of the metal cover 110. The power chip 120 is bonded on the metal cover 110 and is located in the recess 111. The thermal conductive material 130 fills the recess 111 and surrounds the power chip 120. At least one first electrode 121 of the power chip 120 is exposed out of the thermal conductive material 130.

In terms of heat dissipation, the power chip package 100, 100a, 100b and 100c use the thermal conductive material 130 to quickly conduct the heat generated by the power chip 120 to the metal cover 110. The metal cover 110 may provide a multi-faceted heat dissipation type to increase a heat dissipation area for effectively improving a heat dissipation effect. In addition, the power chip 120 is bonded on the metal cover 110, which can omit a chip carrier, to be helpful for thinning and lightening, which is beneficial to the variation of a power module for back-end customers, and can reduce cost.

Referring to FIG. 1A, in a first embodiment of the power chip package 100, the power chip 120 includes a substrate 120S and a semiconductor structure layer 123. The substrate 120S is made of one of silicon carbide, silicon, gallium oxide and gallium nitride. In a silicon carbide substrate 122, the silicon carbide substrate 122 includes a second electrode 124, and the second electrode 124 of the silicon carbide substrate 122 is bonded on the metal cover 110. In other words, the second electrode 124 is electrically connected to the metal cover 110. The second electrode 124 may be a drain. The semiconductor structure layer 123 is disposed on the silicon carbide substrate 122. The first electrode 121 is electrically connected to the semiconductor structure layer 123. The first electrode 121 may be a source and a gate. The power chip 120 is electrically connected to the outside by the first electrode 121 on the semiconductor structure layer 123 and the metal cover 110 connected to the second electrode 124.

Continue referring to FIG. 1B, in a second embodiment of the power chip package 100a, the power chip 120 includes a silicon substrate 122a and a semiconductor structure layer 123. The silicon substrate 122a is bonded on an inner side of the metal cover 110. In other words, the silicon substrate 122a is located in the recess 111 of the metal cover 110. The metal cover 110 is grounded. In other words, an outer side of the metal cover 110 is grounded. The semiconductor structure layer 123 is disposed on the silicon substrate 122a. The first electrode 121 is electrically connected to the semiconductor structure layer 123. The semiconductor structure layer 123 is located between the first electrode 121 and the silicon substrate 122a. The semiconductor structure layer 123 of the power chip 120 may include gallium nitride.

In addition, a quantity of the first electrode 121 may be one or plural. When the power chip 120 is designed as a transistor, the source and the gate are the first electrode 121, and the drain is the second electrode 124. When the power chip 120 is designed as a diode, the source can be the first electrode 121, and the drain can be the second electrode 124. Alternatively, the drain can be the first electrode 121, and the source can be the second electrode 124.

Continue referring to FIG. 1C and FIG. 1D, in a third and fourth embodiments of the power chip packages 100b and 100c, the power chip 120 includes not only the semiconductor structure layer 123, but also an insulation substrate 122b or 122c. The insulation substrate 112b and 112c is boned on the inner side of the metal cover 110. In other words, the insulation substrate 112b and 112c is located in the recess 111 of the metal cover 110. The semiconductor structure layer 123 is disposed on the insulation substrate 112b or 112c. The first electrode 121 is electrically connected to the semiconductor structure layer 123. In the power chip package 110b, the semiconductor structure layer 123 is located between the first electrode 121 and the insulation substrate 112b. In the power chip package 110c, the semiconductor structure layer 123 is located between the first electrode 121 and the insulation substrate 112c.

In some examples, the metal cover 110 can be made of copper metal, aluminum metal or other thermally and electrically conductive metals. In some examples, the metal cover 110 includes a connecting plate portion 112 and a surrounding wall portion 113. An inner side surface 112 is of the connecting plate portion 112 is flat and metallized, such as electroplating gold, chemical plating gold or chemical plating silver, which is helpful for the power chip 120 to be bonded on the inner side surface 112is of the connecting plate portion 112. The surrounding wall portion 113 is formed on an outer edge of the connecting plate portion 112, and the above mentioned recess 111 is enclosed by the surrounding wall portion 113 and the connecting plate portion 112.

In the above mention, the first electrode 121 includes a primary portion 121 p and an extension portion 121e. The primary portion 121p is connected to the semiconductor structure layer 123. The extension portion 121e is connected to the primary portion 121p. That is, the primary portion 121p is located between the semiconductor structure layer 123 and the extension portion 121e. Wherein, a material of the extension portion 121e can be a group consisting of tin/silver/copper, tin/copper, tin/sliver, tin/bismuth, tin/antimony. A material of the primary portion 121p can be a group consisting of gold, gold/tin, tin/sliver/bismuth, tin/silver/bismuth/copper.

An outer side surface 112os of the connecting plate portion 112 and a peripheral surface 113s of the surrounding wall portion 113 can provide heat dissipation. In some examples, in a top view, an outer contour shape of the metal cover 110 is roughly quadrilateral. The outer side surface 112os of the connecting plate portion 112 and a peripheral surface 113s of the surrounding wall portion 113 can provide heat dissipation, wherein the peripheral surface 113s of the surrounding wall portion 113 includes four outer side surfaces. Since the thermal conductive material 130 fills the recess 11, the thermal conductive material 130 exposed on the metal cover 110 can also provide heat dissipation. In other words, the power chip package 100, 100a, 100b and 100c adopts the metal cover 110 and the thermal conductive material 130 to form the multi-faceted heat dissipation type, so as to increase the heat dissipation area and effectively improve the heat dissipation capability.

As shown in FIG. 1A, the metal cover 110 further includes a rough portion 114. The rough portion 114 is disposed on an inner side surface of the surrounding wall portion 113. The rough portion 114 may extend continuously around the thermal conductive material 130, or the rough portion 114 may extend discontinuously around the thermal conductive material 130. The rough portion 114 is directly contacted with the thermal conductive material 130, and a combining surface between the rough portion 114 and the thermal conductive material 130 is concave-convex. The rough portion 114 is used to provide an embedding combining effect, so that the thermal conductive material 130 doesn't fall out of the metal cover 110. That is to improve a combining stability and a reliability between the thermal conductive material 130 and the metal cover 110.

Continue referring to FIG. 1A, the metal cover 110 further includes at least one stopper 115. The stopper 115 is protruded out of the inner side surface of the surrounding wall portion 113. A quantity of the stopper 115 can be one, and the stopper 115 extends to a end surface of the surrounding wall portion 113, or the stopper does not extend to the end surface of the surrounding wall portion 113. Or the quantity of the stopper 115 can be plural, the stopper 115 closest to the end surface of the surrounding wall portion 113 can extend to the end surface of the surrounding wall portion 113, and the other does not extend to the end surface of the surrounding wall portion 113, wherein the stoppers 115 may be spaced apart from each other. The stopper 115 may continuously extend around the thermal conductive material 130, or the stopper 115 may discontinuously extend around the thermal conductive material 130. The stopper 115 is directly contacted with the thermal conductive material 130.

The stopper 115 is used to stop the thermal conductive material 130, so that the thermal conductive material 130 doesn't fall out of the metal cover 110. That is to improve the combining stability and the reliability between the thermal conductive material 130 and the metal cover 110. In addition, when the power chip package 100 is soldered to the circuit board 200, an embedding structural strength between the thermal conductive material 130 and the metal cover 110 can be strengthen by the stopper 115, and indirectly through a fixing strength between the thermal conductive material 130 and the metal cover 110, a bonding quality between the power chip 120 and the metal cover 110 is enhanced and protected, and at the same time an infiltrating path of the external moisture is increased, thereby improving an ability to block an infiltration of the external moisture.

Continue referring to FIG. 1A, the metal cover 110 further includes a protrusion 116. The protrusion 116 is protruded out of an outer side surface of the surrounding wall portion 113, and the protrusion 116 extends to the end surface of the surrounding wall portion 113. When the power chip package 100 is soldered to the circuit board 200, the protrusion 116 can increase a soldering area between the power chip package 100 and the circuit board 200, improve a bonding strength, and improve the ability to block the infiltration of the moisture.

The power chip 120 is bonded on the metal cover 110. A bonded means can be a metal eutectic method or a metal sintering method. A material of the metal eutectic method is selected from a group consisting of gold/tin, tin/silver/copper, tin/silver/bismuth, tin/silver/copper. The metal sintering method may be sliver sintering or copper sintering.

In some examples, the thermal conductive material 130 is an electrically insulating material. The thermal conductive material 130 is a macromolecule compound material with polymer as a matrix and thermal conductive powder as a filler, which has a good thermal conductivity and a good mechanical property. A material of the thermal conductive powder can be carbon, aluminum nitride, boron nitride, silicon carbide, aluminum oxide, zinc oxide, graphene.

In some examples, the thermal conductive material 130 can extend to an outer periphery of the first electrode 121, wherein a end surface of the first electrode 121 is coplanar with a end surface of the thermal conductive material 130. That is, the thermal conductive material 130 can extend to an outer periphery of the extension portion 121e, wherein a end surface of the extension portion 121e is coplanar with the end surface of the thermal conductive material 130. As shown in FIG. 1 D, the thermal conductive material 130 doesn't extend to the first electrode 121.

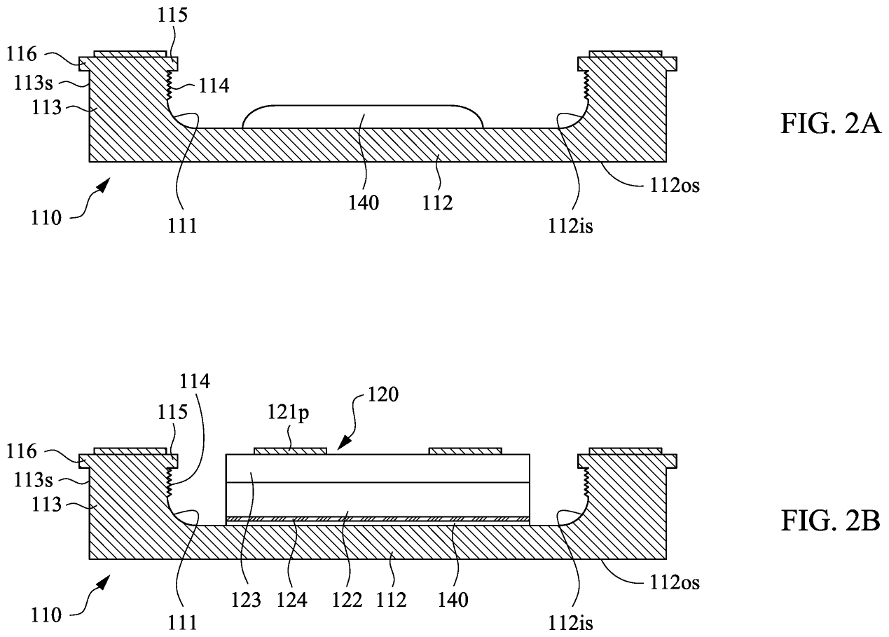

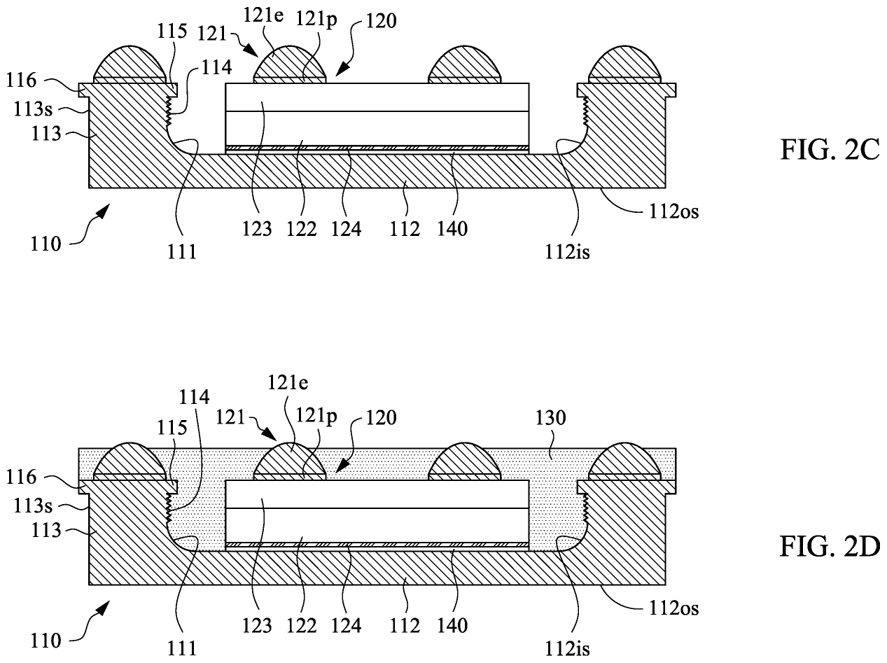

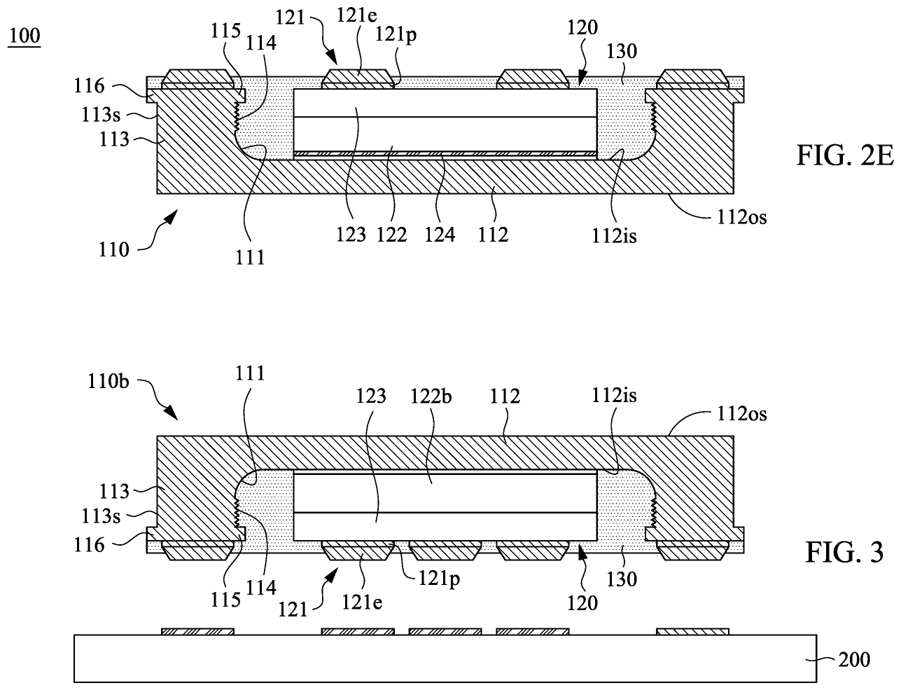

Referring to FIG. 2A to FIG. 2E, which are cross-sectional views to illustrate a method of the power chip package 100 in accordance with the first embodiment of the present invention. Firstly, preparing the metal cover 110. As shown in FIG. 2A, coating a metal welding material 140 on the inner side surface of the connecting plate portion 112 of the metal cover 110. The metal welding material 140 can be nano-sliver, nano-copper, tin/sliver/copper alloy or gold/tin alloy, etc.

As shown in FIG. 2B, then bonding the power chip 120, the power chip 120 is bonded to the connecting plate portion 112 by using the metal welding material 140. That is, the power chip 120 is connected to the connecting plate portion 112 by metallic bonding.

As shown in FIG. 2C, then applying a welding material on a top surface of the metal cover 110 and the primary portion 121p of the power chip 120, and then reflowing the welding material to melt and solidify to form the extension portion 121e on the primary portion 121p of the power chip 120. The welding material is selected from a group consisting of tin/silver/copper, tin/copper, tin/sliver, tin/bismuth, tin/antimony, silver, copper, indium silver.

As shown in FIG. 2D, then filling a thermal interface material into the recess 111 of the metal cover 110 to form the thermal conductive material 130. At this time, a top surface of the thermal conductive material 130 may be protruded out of the primary portion 121p of the first electrode 121, but not be protruded out of the extension portion 121e of the first electrode 121, so that the thermal conductive material 130 doesn't completely cover each extension portion 121e.

As shown in FIG. 2E, then grinding the extension portions 121e to make the height of the extension portions 121e consistent. That is, the end surfaces of the ground extension portions 121e are coplanar, so as to facilitate a subsequent welding operation. In addition, the height of the ground may be greater than 20 micrometers. In addition, the materials of the thermal conductive material 130 and the extension portion 121e are different, so after grinding, the top surface of the thermal conductive material 130 is lower than the top surface of the extension portion 121e. That is, the extension portion 121e is protruded out of the thermal conductive material 130.

Referring to FIG. 3, which is a cross-sectional view to illustrate the power chip package 100b in accordance with the third embodiment of the present invention, showing the power chip package 100b is disposed on the circuit board 200. The power chip package 100b is soldered to the circuit board 200 and is electrically connected to the circuit board 200 by the first electrode 121.

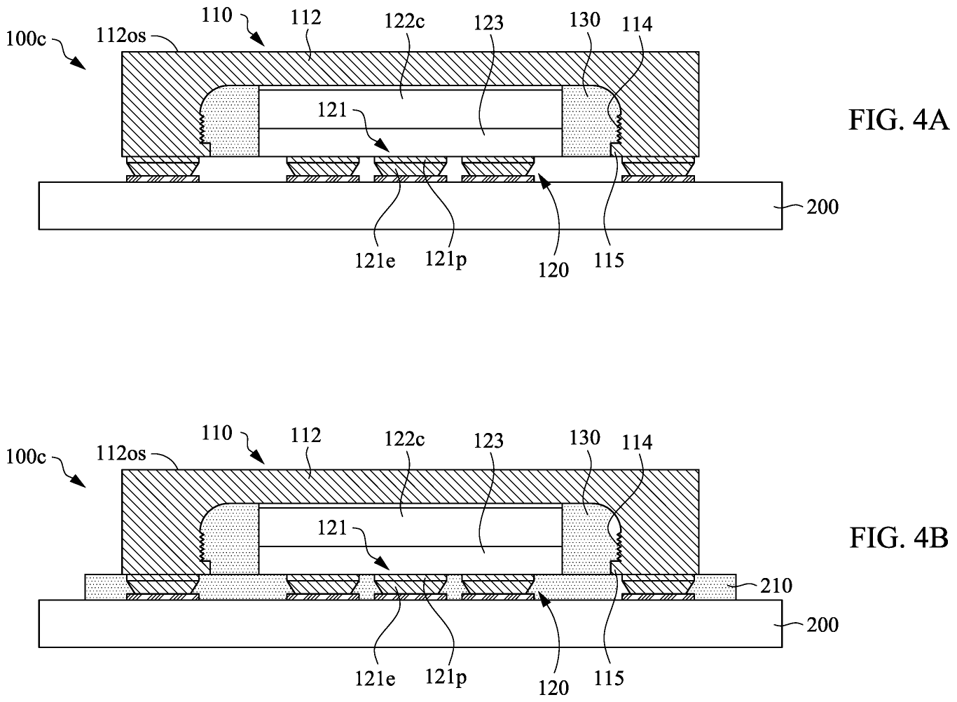

Referring to FIG. 4A and FIG. 4B, the power chip package 100c is soldered to the circuit board 200 and is electrically connected to the circuit board 200 by the first electrode 121. Since the thermal conductive material 130 doesn't extend to the electrodes 121, a gap between the power chip package 100c and the circuit board 200 is filled with an underfill 210. The underfill 210 can intensively protect a welding quality between the power chip package 100c and the circuit board 200, assist heat conduction to improve the heat dissipation effect, and block the infiltration of the moisture.

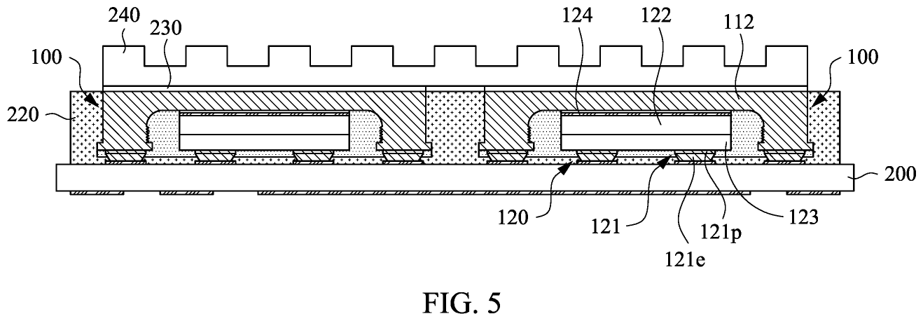

Referring to FIG. 5, which is a cross-sectional view to illustrate the power chip package 100 in accordance with the first embodiment of the present invention, showing the power chip package 100 is packaged on the circuit board 200. According to the usage requirements, plural power chip packages 100 can be disposed on the circuit board 200, and these power chip packages 100 and the circuit board 200 are packaged by a polymeric resin 220, which is convenient for users to design various types of power modules. In an example, an insulation thermal conductive material 230 is a thermal interface material and is formed by coating the outer side surface 112os of the connecting plate portion 112, and a heat dissipation fin 240 is disposed on the outer side surface 112os of the connecting plate portion 112 by the insulation thermal conductive material 230, and a heat dissipation of the power module is improved by the heat dissipation fin 240. In an example, the insulation thermal conductive material 230 is a metal ceramic insulating circuit board. The metal ceramic insulating circuit board includes a ceramic base, a bottom thermal conductive metal, and a top thermal conductive metal. The bottom thermal conductive metal may be copper, aluminum, or copper aluminum alloy, is disposed on a bottom surface of the ceramic base, and is bonded on the metal covers of the power chip packages 100. The top thermal conductive metal may be copper, aluminum, or copper aluminum alloy and is disposed on a top surface of the ceramic base. The heat dissipation fin 240 is bonded on the top thermal conductive metal in the insulation thermal conductive material 230.

Accordingly, the power chip package adopts a configuration of the metal cover and the thermal conductive material, so that the heat generated by the power chip can be quickly transmitted to the metal cover by the thermal conductive material, and the side surface, which is exposed out of the metal cover, of the thermal conductive material and an outer periphery of the metal cover are used to dissipate the heat. In other words, the top surface, bottom surface and outer side surface of the power chip package can dissipate the heat, so the heat dissipation effect is good. In addition, the power chip is bonded on the metal cover, which can omit the chip carrier, to be helpful for thinning and lightening.

Although the present disclosure has been disclosed above with embodiments, it is not intended to limit the present disclosure. Any person having ordinary skill in the art can make various changes and modifications without departing from the spirit and scope of the present disclosure. Therefore, the protection scope of the present disclosure should be defined by the scope of the appended claims.

What is claimed is:

1. A power chip package, comprising:
a metal cover comprising a recess formed on a side surface of the metal cover;
a power chip bonded on the metal cover and located in the recess; and
a thermal conductive material filling the recess and surrounding the power chip, wherein at least one first electrode of the power chip is exposed out of the thermal conductive material.

2. The power chip package of claim 1, wherein the power chip comprises a substrate and a semiconductor structure layer,
wherein the substrate comprises a second electrode bonded on the metal cover, the semiconductor structure is disposed on the substrate, and the at least one first electrode is electrically connected to the semiconductor structure layer.

3. The power chip package of claim 2, wherein the substrate is made of one of silicon carbide, silicon, gallium oxide and gallium nitride.

4. The power chip package of claim 1, wherein the power chip comprises a silicon substrate and a semiconductor structure layer, the silicon substrate is bonded on an inner side of the metal cover, an outer side of the metal cover is grounded, the semiconductor structure layer is disposed on the silicon substrate, the at least one first electrode is connected to the semiconductor structure layer, and the semiconductor structure layer is located between the at least one first electrode and the silicon substrate.

5. The power chip package of claim 1, wherein the power chip comprises a insulation substrate and a semiconductor structure layer, the insulation substrate is bonded on an inner side of the metal cover, the semiconductor structure layer is disposed on the insulation substrate, the at least one first electrode is connected to the semiconductor structure layer, and the semiconductor structure layer is located between the at least one first electrode and the insulation substrate.

6. The power chip package of claim 2, wherein each of the at least one first electrode comprises a primary portion and an extension portion, the primary portion is located between the semiconductor structure layer and the extension portion, a material of the extension portion is selected from a group consisting of tin/silver/copper, tin/copper, tin/sliver, tin/bismuth, tin/antimony, silver, copper, and indium sliver.

7. The power chip package of claim 1, wherein the thermal conductive material extends to the at least one first electrode.

8. The power chip package of claim 7, wherein an end surface of each of the at least one first electrode is coplanar with an end surface of the thermal conductive material.

9. The power chip package of claim 7, wherein the at least one first electrode is protruded out of an end surface of the thermal conductive material.

10. The power chip package of claim 1, wherein the thermal conductive material is indirectly connected to an end surface of each of the at least one first electrode.

11. The power chip package of claim 1, wherein the metal cover comprises a connecting plate portion and a surrounding wall portion, the power chip is bonded on the connecting plate portion, the surrounding wall portion is formed on an outer edge of the connecting plate portion, and the recess of the metal cover is enclosed by the surrounding wall portion and the connecting plate portion.

12. The power chip package of claim 11, wherein the metal cover further comprises a rough portion, the rough portion is disposed on an inner side surface of the surrounding wall portion.

13. The power chip package of claim 11, wherein the metal cover further comprises at least one stopper, the at least one stopper is protruded out of an inner side surface of the surrounding wall portion.

14. The power chip package of claim 13, wherein the at least one stopper extends to an end surface of the surrounding wall portion.

15. The power chip package of claim 13, wherein the at least one stopper is indirectly connected to an end surface of the surrounding wall portion.

16. The power chip package of claim 13, wherein a quantity of the at least one stopper is more than two, one of the at least one stopper is adjacent to and extends to an end surface of the surrounding wall portion, and another of the at least one stopper is indirectly connected to the end surface of the surrounding wall portion.

17. A power module, comprising:
a circuit board;
a plurality of power chip packages of claim 1 disposed on the circuit board; and
a polymeric resin packaging the power chip packages on the circuit board.

18. The power module of claim 17, wherein the power module comprises:
a heat dissipation fin disposed on the metal covers of the power chip packages; and
an insulation thermal conductive material disposed on the metal covers of the power chip packages and located between the metal covers and the heat dissipation fin.
